(19) United States
(12) Patent Application Publication
(10) Pub. No.: US 2003/0098702 A1
(43) Pub. Date: May 29, 2003

(54) Probe card and probe contact method

(75) Inventors: Tsutomu Tatematsu, Kawasaki (JP); Kenji Togashi, Kawasaki (JP); Tetsuhiro Nanbu, Kawasaki (JP); Shigenobu Ishihara, Kawasaki (JP); Morihiko Hamada, Kawasaki (JP); Yoshikazu Arisaka, Kawasaki (JP); Kunihiro Itagaki, Kawasaki (JP)

Correspondence Address: STAAS & HALSEY LLP, 700 11TH STREET, NW, SUITE 500, WASHINGTON, DC, 20001, US

(73) Assignee: Fujitsu Limited, Kawasaki (JP)

(21) Appl. No.: 10/108,338

(22) Filed: Mar. 29, 2002

(30) Foreign Application Priority Data
Nov. 29, 2001 (JP) 2001-364108

(51) Int. Cl. G01R 31/02

(52) U.S. Cl. 324/757

(57) ABSTRACT

An inexpensive probing card that has probe pins for contacting pads with high reliability. The probe pins are arranged on a base plate. The probe pins move along the pads when contacting the pads. A stopper restricts the movement of the probe pins.

### BACKGROUND OF THE INVENTION

The present invention relates to a probe card for testing a semiconductor device and a semiconductor substrate.

When manufacturing a semiconductor device, a probing test is normally conducted to test the conductivity of a wafer. In the probing test, a plurality of probes respectively contact a plurality of pads, which are formed on the wafer. Various properties of the semiconductor device are measured in accordance with probing test programs. The enlargement of recent semiconductor circuits has increased the number of pads. However, the area of each pad has decreased. To shorten the time required for the probing test, it is important that the contact between the probes and the pads be guaranteed.

A probe card, which has a plurality of probes, is used during the probing test. A probing device causes the probes to contact the pads of a wafer with a predetermined contact pressure. More specifically, referring to FIG. 1A, the probing device causes each probe pin 3 to approach a corresponding pad 2, which is formed on a wafer substrate 1. Then, the probing device lifts the wafer substrate 1 by distance A and presses the pad 2 against the probe pin 3.

In the prior art, the distance A must be great enough to guarantee that each probe pin 3 contacts the pad 2. However, as the wafer substrate 1 rises, the distal end of the probe pin 3 bites into the pad 2 and moves in the direction indicated by arrow B. This removes the surface of the pad 2 and forms a pit 4 (FIG. 2). If the distance A is too large, the pit 4 becomes relatively long (large), and a relatively large amount of material, which is removed from the pad 2, is adhered to the distal end of the probe pin 3.

The recent pads are thin. Thus, the distal ends of the probe pins 3 may reach the underlying layers of the pads 2. In such case, metal material, such as aluminum (Al), gold (Au), and nickel (Ni), may adhere to the distal ends of the probe pins 3. When the probing device tests a plurality of electronic devices, the probe pins 3 are repetitively pressed against the corresponding pads 2 of the electronic devices. This deposits the materials of the pads 2 and the underlying layers on the distal ends of the probe pins 3. The deposition of the materials causes contact failure between the probe pins 3 and the pads 2 and decreases the reliability of the probing test.

Due to the higher integration and increased functions of recent electronic devices, many complicated tests must be conducted during the probing test. Thus, the probe pins 3 repetitively contact the same pads 2. In such case, the probe pins 3 repetitively remove material from the corresponding pads 2 and enlarge the pits 4. This results in bonding deficiencies between bonding wires and the pads 2 during a subsequent bonding process.

An increase in the number of pads has increased the number of probes. Thus, a probe card nowadays has 600 to 800 and in some cases more than 1,000 probes that are arranged with a narrow interval between one another. To arrange a large number of probes on a probe card, the inclination angle α between the pads 2 and the corresponding probe pins 3 is relatively small. As a result, it is difficult for the probe pins 3 to contact the pads with sufficient pressure.

Japanese Laid-Open Patent Publication No. 11-142437 describes a probe card provided with a guide plate having a guide hole to guide a probe pin. Although the probe card increases the positioning accuracy of the probe pin, it is difficult to optimally adjust the contact pressure between the probe pin and the pad. Further, the guide hole must be machined with high accuracy. This increases the manufacturing cost of the probing device.

Japanese Laid-Open Patent Publication No. 2000-327402 describes the material of a guide that guides a probe. The material enables fine machining of the guide and improves the accuracy of the contact position between the probe and the pad. However, since the guide is made of a special material, the cost of the probing device increases.

Japanese Laid-Open Patent Publication No. 2001-108708 describes a probe card having a guide that decreases the moving amount of the probe relative to the pad. However, the guide requires high machining accuracy. This increases the manufacturing cost of the probe card. Further, it is difficult to have the probe, which becomes thinner at positions closer to the distal end, contact the pad with sufficient contact pressure.

### SUMMARY OF THE INVENTION

It is an object of the present invention to provide an inexpensive probing card that has a probe contact a pad with high reliability.

To achieve the above object, the present invention provides a probe card used to test an electronic device having a contacted body. The probe card includes a base plate and a probe arranged on the base plate. The probe has a distal end that contacts the contacted body and moves in a predetermined direction when contacting the contacted body. A stopper is arranged on the base plate to restrict the movement of the probe.

A further perspective of the present invention is a method for having a probe contact a contacted body. The probe extends from a peripheral portion of a base plate toward a middle portion of the base plate. The method includes moving the probe toward the middle portion of the base plate while the probe contacts the contacted body, and restricting the movement of the probe with a stopper.

A further perspective of the present invention is a method for having a probe contact a contacted body. The probe has a basal end fixed to a peripheral portion of a base plate, an intermediate portion extending toward a middle portion of the base plate, and a distal end bent toward the peripheral portion of the base plate. The method includes moving the probe toward the peripheral portion of the base plate while the probe contacts the contacted body, and restricting the movement of the probe with a stopper.

A further perspective of the present invention is a probe card used to test an electronic device having a contacted body. The probe card includes a base plate and a plurality of probes arranged on the base plate. Each of the probes has a distal end that contacts the contacted body and moves in a predetermined direction when contacting the contacted body. A stopper is arranged on the base plate for restricting the movement of the probe. The stopper has a side surface separated from the probes by a predetermined distance.

A further perspective of the present invention is a method for manufacturing a probe card that is used to test an electronic device having a contacted body. The method includes preparing a probe and a base plate having an opening, and inserting a stopper in the opening so that a side surface of the stopper is separated from a distal end of the probe by a predetermined distance.

A further perspective of the present invention is a method for manufacturing a probe card that is used to test an electronic device having a contacted body. The method includes preparing a probe and a base plate having a support. The probe has a basal end fixed to a peripheral portion of a base plate, an intermediate portion extending toward a middle portion of the base plate, and a distal end bent toward the peripheral portion of the base plate. The support supports the intermediate portion of the probe. The method further includes attaching a stopper to the support. The stopper has a side surface located near the distal end of the probe.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIGS. 1A and 1B are side views showing a prior art probe in a state contacting a pad;

FIG. 2 is a plan view showing a pit formed in the pad by the probe of FIGS. 1A and 1B;

FIG. 3 is a side view showing a probe card according to a first embodiment of the present invention;

FIG. 4 is an exploded perspective view showing the probe card of FIG. 3;

FIG. 5 is a perspective view showing the probe card of FIG. 3;

FIG. 6 is a bottom view showing the probe card of FIG. 3;

FIGS. 7A and 7B are side views showing a probe and a pad;

FIG. 8 is a plan view showing a pit formed in a pad by the probe card of FIG. 3;

FIGS. 9 and 10 are bottom views showing a stopper and the distal ends of probes; and

FIG. 11 is a side view showing a probe card according to a second embodiment of the present invention.

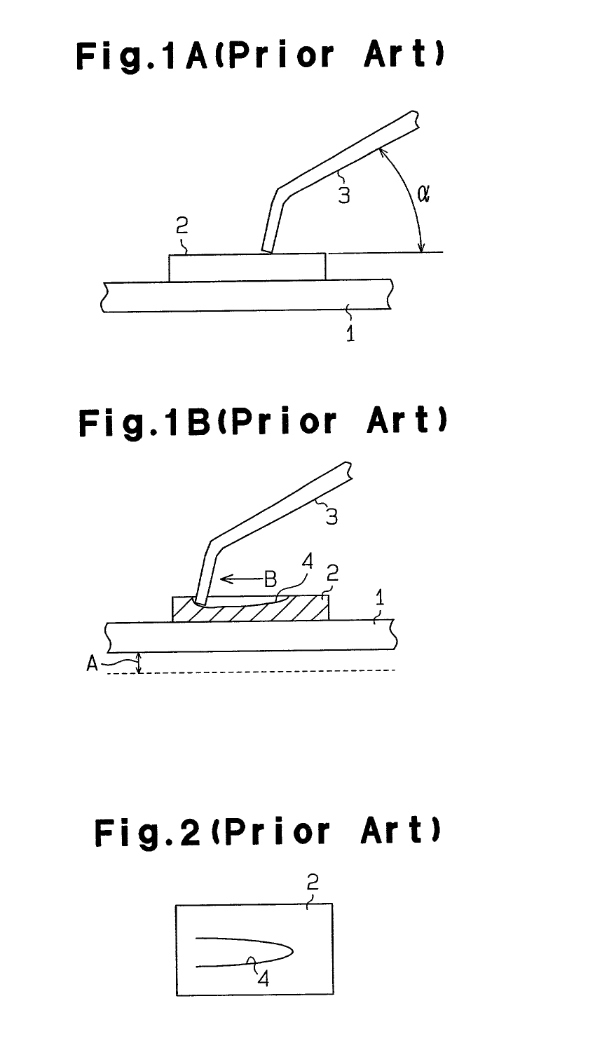

### DETAILED DESCRIPTION OF THE PREFERRED EMBODIMENTS

### First Embodiment

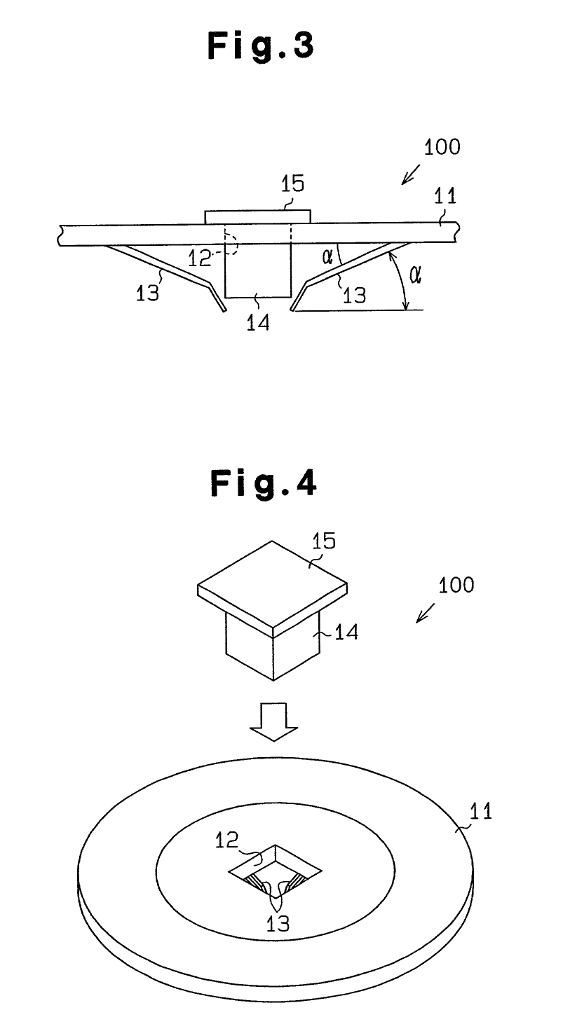

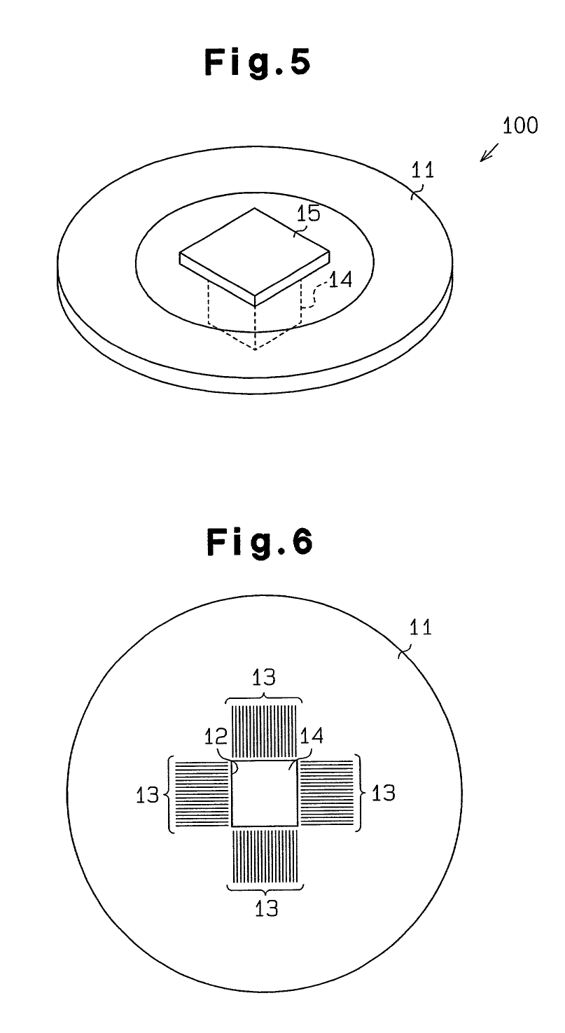

A probe card 100 according to a first embodiment of the present invention will now be discussed with reference to FIGS. 3 to 6. Referring to FIG. 4, the probe card 100 includes a base plate 11, a plurality of probe pins 13 attached to the base plate 11, and a stopper 14 secured to the base plate 11. The base plate 11 is made of an electrically insulative material. An opening 12 extends through the center of the base plate 11 to receive the stopper 14.

Referring to FIG. 6, a plurality of probe pins 13 are arranged on the lower surface of the base plate 11 so as to surround the opening 12. The probe pins 13 are preferably made of a material such as tungsten or BeCu. The basal ends of the probe pins 13 are supported by the base plate 11 along the sides of the opening 12.

A plurality of wires (not shown) surrounding the opening 12 are connected to the probe pins 13 and to lands (not shown) formed along the peripheral portion of the base plate 11. Accordingly, the probe pins 13 are connected to a probing device by the wires and the lands.

Referring to FIG. 3, each of the probe pins 13 extend diagonally downward toward the opening 12 at a predetermined inclination angle α. Each probe pin 13 has a distal end, which is bent downward. The angle formed between the distal end of the probe pin 13 and a pad is greater than the inclination angle α.

An engaging piece 15, which is arranged on the top of the stopper 14, is larger than the opening 12. The engaging piece 15 is made of an electrically insulative material, such as alumina ceramic.

The stopper 14 is inserted in the opening 12 and the engaging piece 15 is fixed to the base plate 11 to secure the stopper 14 to the base plate 11. The probe card 100 is assembled in this manner. In this state, referring to FIG. 6, the distal ends of the probe pins 13 surround the stopper 14. It is preferred that the stopper 14 be separated from the distal ends of the probe pins 13 by 5 to 15 μm. Further, the distal ends of the probe pins 13 are located at a level that is lower than the bottom end of the stopper 14.

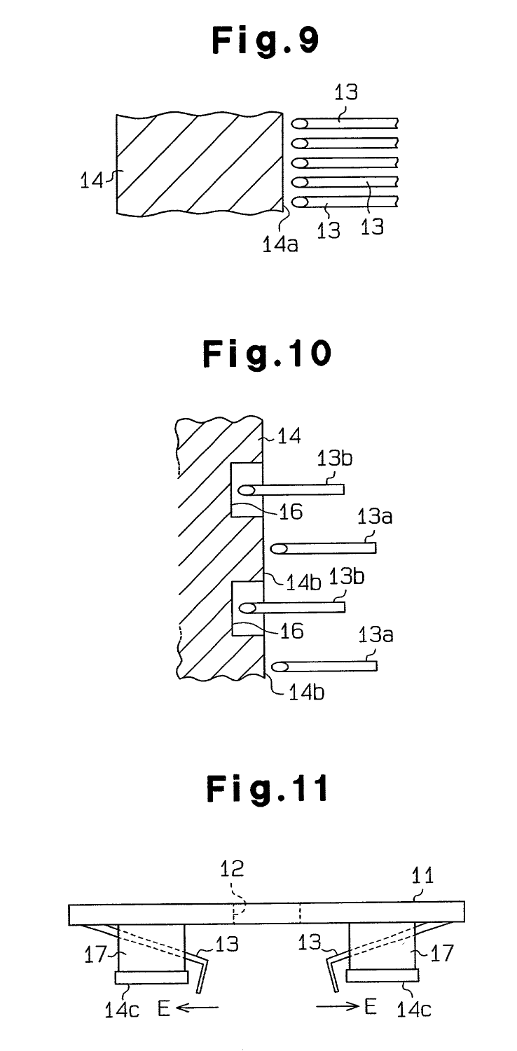

To attach as many probe pins 13 as possible to the base plate 11, the area of which is limited, the basal ends of the probe pins 13 are supported by the base plate 11 in a stepped manner. Further, the distal end of the probe pins 13 located on one side of the stopper 14 may be arranged along the same line, as shown in FIG. 9. Alternatively, the distal end of the probe pins 13 may be arranged so that they extend in an alternate manner, as shown in FIG. 10.

Referring to FIG. 9, when the distal ends of the probe pins 13 are arranged along the same line, it is preferred that the stopper 14 have a flat side surface 14a.

Referring to FIG. 10, when the probe card 100 has probe pins 13a, 13b, which extend alternately toward the middle portion of the base plate 11, slots 16 are formed in the stopper 14 so that an equal distance is always maintained between the probe pins 13a, 13b and the stopper 14. More specifically, the probe card 100 of FIG. 10 has the probe pins 13a, the distal ends of which are arranged along a first line, and the probe pins 13b, the distal ends of which are arranged along a second line. The sides of the stopper 14 each include an outer surface 14b, which opposes the probe pins 13b, and the slots 16, which oppose the probe pins 13b. The slots 16 are formed so that the distance between the slots 16 and the corresponding probe pins 13b is equal to the distance between the outer surfaces 14b and the corresponding probe pins 13a.

The operation of the probe card 100 will now be discussed.

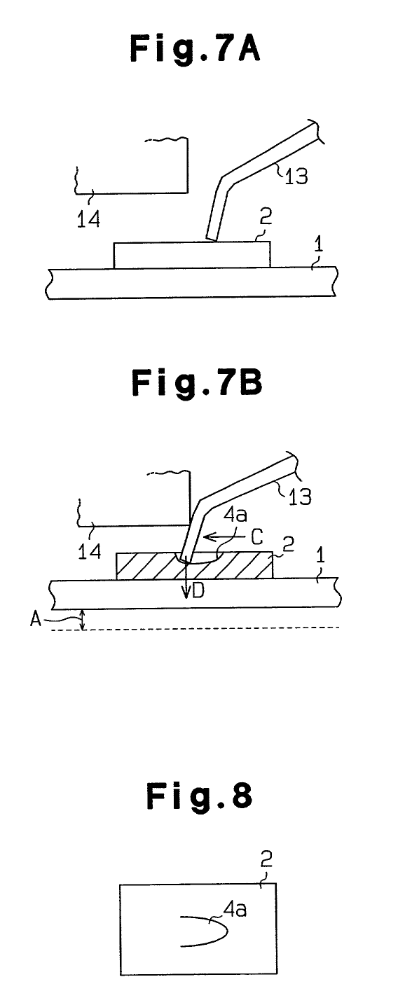

To conduct a probing test, referring to FIG. 7A, the distal ends of the probe pins 13 are moved toward corresponding pads (contacted bodies) 2 on a wafer substrate 1. Referring to FIG. 7B, the probing device then lifts the wafer substrate 1 by a predetermined distance A. This presses the distal ends of the probe pins 13 against the pads 2.

As the wafer substrate 1 rises, the distal ends of the probe pins 13 bite into the corresponding pads 2 and moves toward the stopper 14, as indicated by arrow C. This removes part of the surface of the pad 2 and forms a pit 4a, as shown in FIG. 8. However, the probe pins 13 come into contact with the stopper 14. This restricts further movement of the probe pins 13. After the probe pins 13 contact the stopper 14, the contact pressure D between the probe pins 13 and the pads 2 increases. Accordingly, sufficient contact pressure D is obtained.

The probe card 100 of the first embodiment has the advantages described below.

When the wafer substrate 1 is lifted and the pads 2 contact the probe pins 13, the stopper 14 restricts the sliding of the probe pins 13. This improves the accuracy of the contact position between each probe pin 13 and the corresponding pad 2.

The stopper 14 restricts the sliding of the probe pin 13. Thus, when the wafer substrate 1 is lifted, the probe pins 13 contacts the pads 2 with sufficient contact pressure D. Accordingly, the angle between the pads 2 and the probe pins 13 (i.e., inclination angle α) does not have to be increased.

The stopper 14 decreases the moving distance of the probe pins 13. Thus, the amount of material removed by the probe pins 13 is decreased. This reduces the amount of material that adheres to the probe pins 13. As a result, connection failures between the probe pins 13 and the pads 2 decrease.

The stopper 14 decreases the sliding distance of the probe pins 13. Thus, the pits 4a formed in the surface of the pads 2 are relatively short (small). This prevents bonding deficiencies from occurring between bonding wires and the pads 2 during a bonding process.

The distance between the distal ends of the probe pins 13 and the stopper 14 need only be set at about 5-15 μm and thus does not require high accuracy. Accordingly, the employment of the stopper 14 only slightly increases the manufacturing cost of the probe card 100.

### Second Embodiment

A probe card 200 according to a second embodiment of the present invention will now be discussed with reference to FIG. 11. The probe card 200 includes a plurality of probe pins 13 extending from the peripheral portion of the base plate 11 toward the middle portion of the base plate 11, a support 17 fixed to the base plate 11, and a stopper 14c supported by the support 17.

Each of the probe pins 13 has an intermediate portion, which extends through the support 17, and a distal end, which is bent outward of the base plate 11. The stopper 14c is attached to (supported by) the lower end of the support 17. The stopper 14c is arranged outward of the base plate 11 relative to the distal ends of the probe pins 13. In other words, the distal ends of the probe pins 13 are surrounded by the stopper 14c.

When conducting the probing test, the wafer substrate 1 is lifted so that the probe pins 13 contact the corresponding pads 2. As the wafer substrate 1 rises, the distal ends of the probe pins 13 bite into the pads 2 and move outward of the probe card 20 as indicated by arrows E in FIG. 11. When the probe pins 13 contact the stopper 14c, further movement of the probe pins 13 is restricted.

The movement of the probe pins 13 slightly removes material from the surface of the corresponding pads 2. After the probe pins 13 contacts the stopper 14c, the rising of the wafer substrate 1 increases the contact pressure D between the probe pin 13 and the pad 2. Accordingly, sufficient contact pressure D is obtained.

In addition to the advantages of the first embodiment, the probe card 200 of the second embodiment has the following advantage.

When conducting a heating test while the probe pins 13 contact the pads 2, the probe pins 13 and the support 17 thermally expand. The thermal expansion may displace the distal ends of the probe pins 13. However, the stopper 14c restricts the displacement of the probe pins 13. Accordingly, the contact position and contact pressure of each probe pin 13 is stably maintained even when conducting the heating test.

It should be apparent to those skilled in the art that the present invention may be embodied in many other specific forms without departing from the spirit or scope of the invention. Particularly, it should be understood that the present invention may be embodied in the following forms.

The shape of the stopper 14 in the first embodiment may be changed in accordance with the layout of the pads 2 and the probe pins 13. For example, the stopper 14 does not have to be a square elongated structure and may be a cylindrical structure or another type of elongated polygonal structure.

The present examples and embodiments are to be considered as illustrative and not restrictive, and the invention is not to be limited to the details given herein, but may be modified within the scope and equivalence of the appended claims.

What is claimed is:

1. A probe card used to test an electronic device having a contacted body, the probe card comprising:
a base plate;
a probe arranged on the base plate, wherein the probe has a distal end that contacts the contacted body and moves in a predetermined direction when contacting the contacted body; and
a stopper arranged on the base plate for restricting the movement of the probe.

2. The probe card according to claim 1, wherein the probe has a basal end fixed to a peripheral portion of the base plate, and the distal end of the probe extends toward a middle portion of the base plate, wherein the distal end of the probe moves toward the middle portion of the base plate when contacting the contacted body.

3. The probe card according to claim 2, wherein the stopper is arranged in the middle portion of the base plate.

4. The probe card according to claim 2, wherein the stopper is received in an opening extending through the middle portion of the base plate and has a side surface adjacent to the distal end of the probe.

5. The probe card according to claim 1, wherein
the probe has a basal end fixed to a peripheral portion of the base plate and an intermediate portion extending toward a middle portion of the base plate;
the stopper is arranged between the distal end of the probe and the peripheral portion of the base substrate; and
the distal end of the probe bends outward toward the peripheral portion of the base plate from the intermediate portion and moves toward the middle portion of the base plate when contacting the contacted body.

6. The probe card according to claim 5, further comprising a support for attaching the stopper to the base plate.

7. The probe card according to claim 6, wherein the support supports the intermediate portion of the probe, and the stopper is attached to a lower end of the support.

8. The probe card according to claim 1, wherein the stopper has a side surface separated from the distal end of the probe by a predetermined distance.

9. The probe card according to claim 8, wherein the probe is one of a plurality of probes which are arranged so that their distal ends are along the same line, and the side surface of the stopper is flat.

10. The probe card according to claim 8, wherein the probe is one of a plurality of probes which are arranged so that their distal ends are along different lines, and the side surface of the stopper has a plurality of slots so that the distance between the side surface and the distal ends of all of the probes is equal.

11. The probe card according to claim 8, wherein the probe is one of a plurality of probes that include first probes, which are arranged so that their distal ends are arranged along a first line, and second probes, which are arranged so that their distal ends are arranged along a second line, and wherein the side surface of the stopper includes a surface opposed to the first probes and slots opposed to the second probe.

12. A method for having a probe contact a contacted body, wherein the probe extends from a peripheral portion of a base plate toward a middle portion of the base plate, the method comprising the steps of:
moving the probe toward the middle portion of the base plate while the probe contacts the contacted body; and
restricting the movement of the probe with a stopper.

13. A method for having a probe contact a contacted body, wherein the probe has a basal end fixed to a peripheral portion of a base plate, an intermediate portion extending toward a middle portion of the base plate, and a distal end bent toward the peripheral portion of the base plate, the method comprising the steps of:
moving the probe toward the peripheral portion of the base plate while the probe contacts the contacted body; and
restricting the movement of the probe with a stopper.

14. A probe card used to test an electronic device having a contacted body, the probe card comprising:
a base plate;
a plurality of probes arranged on the base plate, wherein each of the probes has a distal end that contacts the contacted body and moves in a predetermined direction when contacting the contacted body; and
a stopper arranged on the base plate for restricting the movement of the probe, wherein the stopper has a side surface separated from the probes by a predetermined distance.

15. The probe card according to claim 14, wherein the side surface of the stopper is surrounded by the distal ends of the probes.

16. The probe card according to claim 14, wherein the distal ends of the probes surround the stopper.

17. A method for manufacturing a probe card that is used to test an electronic device having a contacted body, the method comprising the steps of:
preparing a probe and a base plate having an opening; and
inserting a stopper in the opening so that a side surface of the stopper is separated from a distal end of the probe by a predetermined distance.

18. A method for manufacturing a probe card that is used to test an electronic device having a contacted body, the method comprising the steps of:
preparing a probe and a base plate having a support, wherein the probe has a basal end fixed to a peripheral portion of a base plate, an intermediate portion extending toward a middle portion of the base plate, and a distal end bent toward the peripheral portion of the base plate, and wherein the support supports the intermediate portion of the probe; and
attaching a stopper to the support, wherein the stopper has a side surface located near the distal end of the probe.
